(19) United States
(12) Patent Application Publication
(10) Pub. No.: US 2026/0214902 A1
(43) Pub. Date: Jul. 23, 2026

(54) CENTER BIT LINE ARCHITECTURE FOR THREE-DIMENSIONAL MEMORY, THREE-DIMENSIONAL MEMORY AND PREPARATION METHOD THEREFOR

(71) Applicant: INSTITUTE OF MICROELECTRONICS, CHINESE ACADEMY OF SCIENCES, Beijing (CN)

(72) Inventors: Gang ZHANG, Beijing (CN); Zongliang HUO, Beijing (CN)

(21) Appl. No.: 19/140,755

(22) PCT Filed: Dec. 22, 2022
(86) PCT No.: PCT/CN2022/141020

§ 371 Date: Jun. 18, 2025

(51) Int. Cl. H10B 43/35; H10B 41/27; H10B 41/35; H10B 43/27

(52) U.S. Cl. CPC H10B 43/35; H10B 41/27; H10B 41/35; H10B 43/27

(57) ABSTRACT

A center bit line architecture for three-dimensional memory, a three-dimensional memory and a preparation method therefor are provided. The center bit line architecture includes: first and second common sources opposite to each other; multiple word line layers stacked between the first common source and the second common source along a first direction; multiple channels passing through multiple word line layers and connected to the first and second common sources, where a string is formed in each channel; and multiple center bit lines arranged in a middle part of the channels and arranged at intervals along a second direction intersecting with the first direction. Multiple word line layers and multiple strings form a block, and multiple center bit lines divide the block into an upper first sub-block and a lower second sub-block, so as to drive strings in the first sub-block and strings in the second sub-block separately.

### CROSS REFERENCE TO RELATED APPLICATION

This application is a National Stage Application of International Application No. PCT/CN2022/141020, filed on Dec. 22, 2022, entitled CENTER BIT LINE FRAMEWORK OF THREE-DIMENSIONAL MEMORY, THREE-DIMENSIONAL MEMORY AND MANUFACTURING METHOD THEREFOR, the entire contents of which are incorporated herein in their entireties by reference.

### TECHNICAL FIELD

The present disclosure relates to the technical field of three-dimensional memory, and in particular to a center bit line architecture for three-dimensional memory, a three-dimensional memory and a preparation method therefor.

### BACKGROUND

As the number of stacked word line layers in a three-dimensional memory continues to increase, for example, from 128 layers to 240 layers then to more than 300 layers, with the page volume remains unchanged (16K byte), the block size of NAND memories continues to increase, from 45 Mbit to 80 Mbit then to more than 140 Mbit. The continuous increase of the block size has posed increasingly high technical difficulties in the improvement of the system performance, as well as great difficulties in the improvement of the product yield. The reduction of the block size becomes a major technical requirement and a technical difficulty in the future.

As the number of the stacked word line layers in the three-dimensional memory continues to increase, the channel length continues to increase, from a range of 5 to 6 microns of 128 layers to a range of 14 to 18 microns of 300 layers. In addition, in order to reduce various types of noise interference, the channel thickness is reduced from a range of 6 to 7 nanometers to a range of 5 to 6 nanometers. As a result, the channel resistance increases sharply and the channel current decreases rapidly. It is estimated that after there are 500 layers stacked, conventional polysilicon channel materials will fail to provide a sufficient current strength to support signal sensing.

Electrical half block erase may partially achieve the reduction of the block size. However, due to large erase interference, the cycling endurance of the electrical half block erase is difficult to meet the actual application requirements. In addition, the half block erase cannot solve the physical bottleneck of channel current reduction.

### SUMMARY

According to a first aspect of the present disclosure, a center bit line architecture for three-dimensional memory is provided, including: a first common source and a second common source arranged opposite to each other; a plurality of word line layers stacked between the first common source and the second common source along a first direction; a plurality of channels passing through the plurality of word line layers and connected to the first common source and the second common source, where a string is formed in each of the plurality of channels; a plurality of center bit lines arranged in a middle part of the channels, and arranged at intervals along a second direction intersecting with the first direction. A combination of the plurality of word line layers and the plurality of strings forms a block, and the plurality of center bit lines divide the block into an upper first sub-block and a lower second sub-block, so as to drive strings in the first sub-block and strings in the second sub-block separately.

Further, the plurality of word line layers are spaced apart from each other, and an insulating layer is arranged between two adjacent word line layers.

Further, each of a word line layer in the first sub-block closest to the first common source and a word line layer in the second sub-block closest to the second common source is used as a bottom select line; and each of a word line layer in the first sub-block closest to the center bit line and a word line layer in the second sub-block closest to the center bit line is used as a string select line.

Further, channels in the first sub-block are connected with channels in the second sub-block respectively through a plurality of center bit line plugs arranged in the middle part, and the center bit line plugs pass through the plurality of center bit lines in a staggered manner.

Further, each of the center bit line plugs is eccentrically arranged with respect to a string connected with the center bit line plug.

Further, a plurality of string select lines are provided, and each of the plurality of string select lines cuts in a staggered manner along a direction in which the plurality of strings are arranged, so as to form a serpentine-like cut.

According to a second aspect of the present disclosure, a three-dimensional memory is provided, including the center bit line architecture for three-dimensional memory mentioned above. According to a third aspect of the present disclosure, a method for preparing the three-dimensional memory is provided, including: step S1, depositing a plurality of stack layers on a substrate, where each of the plurality of stack layers includes a sacrificial layer and an insulating layer; step S2, etching the plurality of stack layers to synchronously form a plurality of channels and word line cuts; step S3, synchronously filling the plurality of channels and the word line cuts with a gate stack and a core insulating layer; step S4, performing wet etching on the gate stack and the core insulating layer in the word line cuts; step S5, removing the sacrificial layers in the plurality of stack layers to replace the sacrificial layers with word line layers, and performing a planarization process, so as to form a lower second sub-block; step S6, sequentially depositing an insulating layer, a string select line cut and an insulating layer on the second sub-block; step S7, forming a plurality of center bit line plugs by etching, and sequentially depositing an insulating layer and a core metal layer in each of the center bit line plugs; step S8, etching the string select line cut, filling the string select line cut with an insulating layer, and performing a planarization process, so as to form a lower string select line; step S9, forming a plurality of center bit lines on the string select line; step S10, repeating the steps S6 to S8 to form an upper string select line; and step S11, repeating the steps S3 to S5 to form an upper first sub-block.

Further, in step S1, the substrate includes a silicon wafer substrate, a material of the sacrificial layer is silicon nitride or doped silicon nitride, and a material of the insulating layer is silicon oxide or a low dielectric constant material.

Further, in step S2, a width of the word line cut is greater than twice a diameter of the channel, and the word line cuts are respectively provided on opposite sides of the plurality of channels.

Further, in step S3, the gate stack includes a TANOS structure, and a material of the core insulating layer includes silicon oxide.

Further, in step S5, a material of the word line layer includes metal tungsten or metal molybdenum.

Further, in step S6, a material of the string select line is a metal material including tungsten, or polysilicon.

Further, in step S7, the plurality of center bit line plugs are arranged at intervals, each of the center bit line plugs is eccentrically arranged with respect to a string connected with the center bit line plug, and the core metal layer includes tungsten.

Further, in step S8, the string select line cut is serpentine-like, and the string select line cut is not deeper than a top of string of the second sub-block.

Further, in step S9, a direction in which the plurality of center bit lines are arranged intersects with a direction in which the word line layers are arranged, the center bit line plugs are arranged at intervals, and the plurality of center bit lines are formed after a planarization process is performed.

### BRIEF DESCRIPTION OF THE DRAWINGS

The above and other objectives, features and advantages of the present disclosure will become clearer through the following description of embodiments of the present disclosure with reference to the accompanying drawings.

FIG. 1 schematically shows a sectional structural diagram of a basic architecture of a conventional three-dimensional memory;

FIG. 2 schematically shows a sectional structural diagram of a center bit line architecture for three-dimensional memory according to an embodiment of the present disclosure;

FIG. 3 schematically shows a sectional view of a center bit line architecture for three-dimensional memory according to an embodiment of the present disclosure and top-view cross-sectional views of parts A and B, where “part A” in the left figure is a top-view cross-sectional view, “part B” in the left figure is a top-view cross-sectional view, and the right figure is the sectional view;

FIG. 4 schematically shows a flowchart of a method for preparing a three-dimensional memory according to another embodiment of the present disclosure;

FIG. 5A schematically shows a sectional view and a partial top-view cross-sectional view of channels and word line cuts obtained by synchronously etching according to another embodiment of the present disclosure, where the left figure is the top-view cross-sectional view, and the right figure is the sectional view;

FIG. 5B schematically shows a sectional view and a partial top-view cross-sectional view of a lower second sub-block according to another embodiment of the present disclosure, where the left figure is the top-view cross-sectional view and the right figure is the sectional view;

FIG. 5C schematically shows a sectional view and a partial top-view cross-sectional view of a lower string select line according to another embodiment of the present disclosure, where the left figure is the top-view cross-sectional view and the right figure is the sectional view;

FIG. 5D schematically shows a sectional view and a partial top-view cross-sectional view of a center bit line according to another embodiment of the present disclosure, where “part A” on the upper left is the top-view cross-sectional view and the right figure is the sectional view;

FIG. 5E schematically shows a partial sectional structural diagram of an upper string select line according to another embodiment of the present disclosure; and

FIG. 5F schematically shows a sectional structural diagram of an upper first sub-block according to another embodiment of the present disclosure.

### REFERENCES SIGNS

ACS1-first common source; ACS2-second common source; bottom select line-bottom select line; string select line-string select line; WL-word line; CBL-center bit line; CBL plug-center bit line plug; SSL cut-string select line cut; string-string; channel-channel; 10-silicon wafer substrate; 201-insulating layer; 202-sacrificial layer; 30-word line cut.

### DETAILED DESCRIPTION OF EMBODIMENTS

Embodiments of the present disclosure will be described below with reference to the accompanying drawings. However, it should be understood that these descriptions are only exemplary and are not intended to limit the scope of the present disclosure. In the following detailed description, for the convenience of explanation, many specific details are set forth to provide a comprehensive understanding of the embodiments of the present disclosure. However, it is obvious that one or more embodiments may also be implemented without these specific details. In addition, in the following description, descriptions of well-known structures and technologies are omitted to avoid unnecessary confusion of the concepts of the present disclosure.

It will be understood that when an element (such as a layer, film, region, or substrate) is described as being “on” another element, it may be directly on the other element or an intervening element may also be present. In addition, in the specification and claims, when an element is described as being “connected” to another element, it may be “directly connected” to the other element, or “connected” to the other element through a third element.

In a detailed description of the embodiments of the present disclosure, for convenience of explanation, a cross-sectional view showing a device structure is not partially enlarged according to a general scale, and a schematic diagram is only an example, which should not limit the scope of the present disclosure. In addition, three-dimensional dimensions of a length, a width and a depth should be included in actual production.

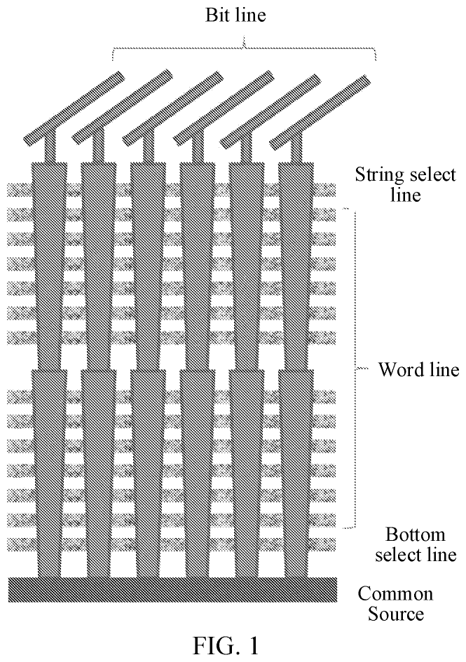

FIG. 1 schematically shows a sectional structural diagram of a basic architecture of a conventional three-dimensional memory.

As shown in FIG. 1, in the basic architecture of the conventional three-dimensional memory, the common source (ACS) is arranged at the bottom of the array and the bit line (BL) is arranged at the top of the array. Each word line (WL) layer forms a page. The channel passes through all word lines to connect the common source and the bit line, so as to form a string. The body composed of all strings and word lines is a block (BLOCK). Usually, a word line layer closest to the common source among the plurality of word line layers is a bottom select line, and a word line layer closest to the bit line among the plurality of word line layers is a string select line.

However, the above basic architecture of the conventional three-dimensional memory has the problems of large block size and large channel resistance.

In view of this, in the present disclosure, a three-dimensional semiconductor memory structure having a center bit line is combined with the integration technology, so as to provide a new center bit line architecture for three-dimensional memory. The present disclosure further provides a three-dimensional memory employing the center bit line architecture for three-dimensional memory, and a method for preparing the three-dimensional memory.

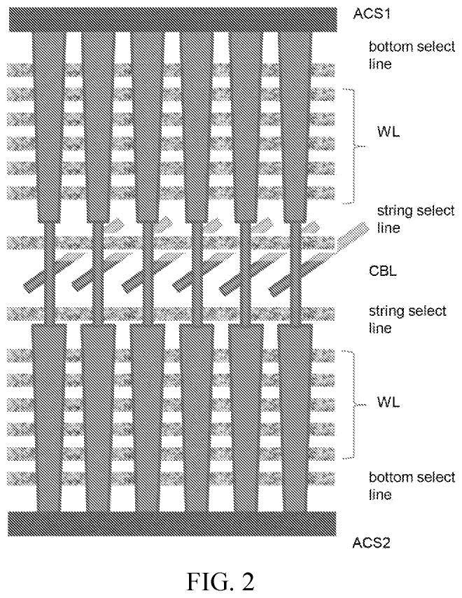

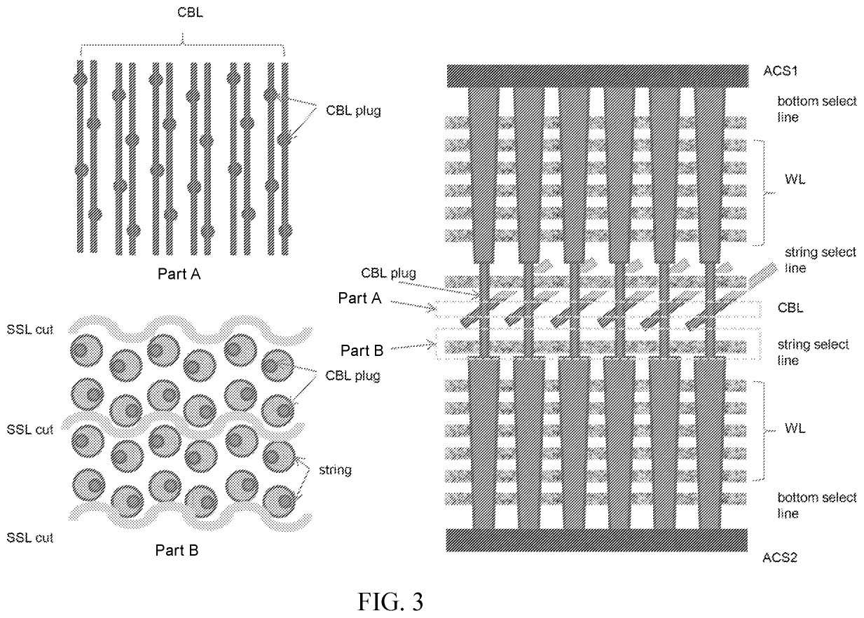

The technical solution(s) of the present disclosure will be described in detail below in combination with a structure of the center bit line architecture for three-dimensional memory according to a specific embodiment of the present disclosure. It will be understood that material layers, shapes and structures of the various parts in the structure of the center bit line architecture for three-dimensional memory shown in the following FIG. 2 to FIG. 3 are merely exemplary to help those skilled in the art understand the technical solution(s) of the present disclosure, and are not intended to limit the scope of protection of the present disclosure.

In a first exemplary embodiment of the present disclosure, a center bit line architecture for three-dimensional memory is provided.

FIG. 2 schematically shows a sectional structural diagram of a center bit line architecture for three-dimensional memory according to an embodiment of the present disclosure.

As shown in FIG. 2, the center bit line architecture for three-dimensional memory according to this embodiment includes: a first common source (ACS1) and a second common source (ACS2) arranged opposite to each other; a plurality of word line (WL) layers stacked between the first common source and the second common source along a first direction; a plurality of channels passing through the plurality of word line layers and connected to the first common source and the second common source, where a string is formed in each of the plurality of channels; and a plurality of center bit lines (CBL) arranged in a middle part of the channels and arranged at intervals along a second direction intersecting with the first direction.

A combination of the plurality of word line layers and the plurality of strings forms a block (BLOCK), and the plurality of center bit lines divide the block into an upper first sub-block and a lower second sub-block, so as to drive strings in the first sub-block and strings in the second sub-block separately.

In this embodiment, the plurality of word line layers are spaced apart from each other, and an insulating layer is arranged between two adjacent word line layers. Specifically, with reference to FIG. 2, between the first common source and the second common source, an insulating layer is stacked on each word line layer, so as to stack the word line layer and the insulating layer in sequence, thereby ensuring that the structure closest to the first common source and the structure closest to the second common source are both insulating layers. In this way, each common source is separated from the word line layer closest to the common source.

In this embodiment, the word line layer in the first sub-block closest to the first common source and the word line layer in the second sub-block closest to the second common source are both used as bottom select lines. The word line layer in the first sub-block closest to the center bit line and the word line layer in the second sub-block closest to the center bit line are both used as string select lines.

FIG. 3 schematically shows a sectional view of a center bit line architecture for three-dimensional memory according to an embodiment of the present disclosure and top-view cross-sectional views of parts A and B, where “part A” in the left figure is a top-view cross-sectional view, “part B” in the left figure is a top-view cross-sectional view, and the right figure is the sectional view.

As shown in FIG. 3, part A is used to show the positional relationship between the center bit line and the center bit line plug, and part B is used to show the positional relationship between the center bit line plug and the string connected with the center bit line plug.

As shown in the top-view cross-sectional view of part A in FIG. 3, in this embodiment, the channels in the first sub-block are connected with channels in the second sub-block respectively through a plurality of center bit line plugs (CBL plugs) arranged in the middle part, and the center bit line plugs pass through the plurality of center bit lines (CBL) in a staggered manner. It may be seen from the figure that in the top-view cross-sectional view, the center bit line plugs pass through the center bit lines, and the center bit line plugs pass through the center bit lines in a staggered manner, so that all the center bit line plugs are arranged in a staggered manner to achieve connections at every other position.

As shown in the top-view cross-sectional view of part B in FIG. 3, in this embodiment, each center bit line plug (CBL plug) is eccentrically arranged with respect to the string connected with the center bit line plug. For example, it may be seen from the figure that, in the top-view cross-sectional view, some of the center bit line plugs are biased to the left with respect to the connected strings, while other center bit line plugs are biased to the right with respect to the connected strings.

Further, with continued reference to the top-view cross-sectional view of part B in FIG. 3, a plurality of string select lines are provided, and each string select line cuts in a staggered manner along a direction in which the plurality of strings are arranged, so as to form a serpentine-like cut (SSL cut). Specifically, it may be seen from the figure that in the first direction (i.e., a direction in which the plurality of word line layers are stacked), the string select lines are respectively arranged above and below the center bit line (CBL). In the second direction (i.e., a direction in which the plurality of center bit lines are arranged in parallel), each string select line cuts in a staggered manner along the direction in which the plurality of strings are arranged, so as to form the serpentine-like cut. For example, in the top-view cross-sectional view, that is, at the same height in the first direction, three serpentine-like cuts (SSL cut) are provided, so that the plurality of strings are evenly distributed in the second direction.

According to the above embodiments, in the center bit line architecture for three-dimensional memory provided in the present disclosure, the center bit lines are arranged inside the memory array to drive the strings in two directions. Two common sources (ACS) are arranged above and below the channels respectively, and the center bit lines (CBL) divide the block into two sub-blocks, which is convenient for system application. When the center bit line architecture is applied, the block size is ½ of the original block size, and the channel length is also ½ of the original channel length. That is, the halving of the block size and the halving of the channel resistance are both achieved.

Likewise, based on the center bit line architecture for three-dimensional memory provided in the present disclosure, according to the number of layers of the embedded word lines in the array, the block size may be reduced to ½, ⅓ or even 1/n, thus the problems of large block size and large channel resistance are both solved. That is, not only the block size may be reduced, but also the channel length (that is, the channel resistance) may be reduced, which is in line with the future development trends of three-dimensional memories.

It will be noted that FIG. 2 and FIG. 3 are only partial structural diagrams of the center bit line architecture for three-dimensional memory provided according to a specific embodiment of the present disclosure, and do not represent limitations on the number of layers of the embedded center bit lines within the array of the center bit line architecture for three-dimensional memory provided in the present disclosure. The number of the layers of the three-dimensional memory, the number of the channel layer arrays, the number of the word line layers and the number of the center bit line layers provided in the present disclosure may each be set according to actual application conditions, which are not limited in the embodiments of the present disclosure.

In a second exemplary embodiment of the present disclosure, a three-dimensional memory is provided, including any center bit line architecture for three-dimensional memory mentioned in the first exemplary embodiment of the present disclosure.

According to the three-dimensional memory provided in this embodiment, based on the number of the layers of the embedded word lines in the array, the block size may be reduced to ½, ⅓ or even 1/n, which may not only reduce the block size, but also reduce the channel length (i.e., the channel resistance), which is in line with the future development trends of three-dimensional memories.

In a third exemplary embodiment of the present disclosure, a method for preparing the above-mentioned three-dimensional memory is provided.

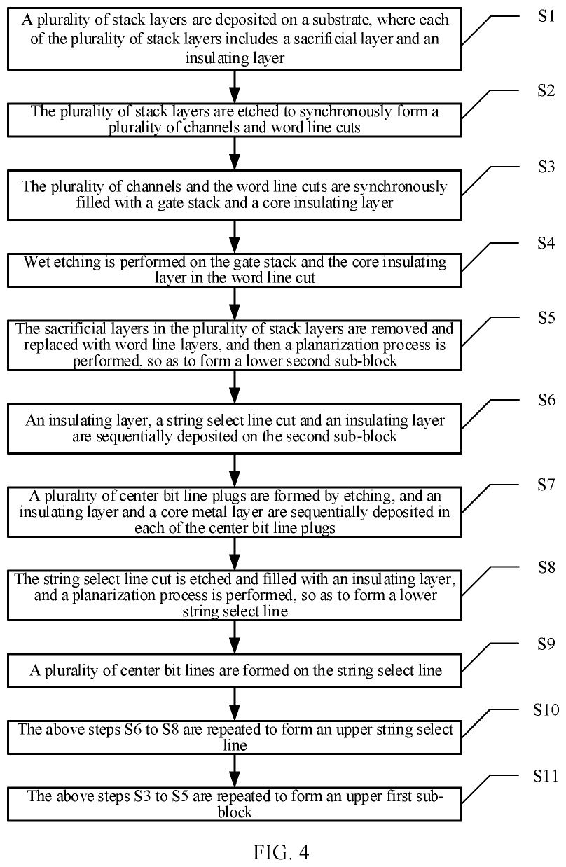

FIG. 4 schematically shows a flowchart of a method for preparing a three-dimensional memory according to another embodiment of the present disclosure.

As shown in FIG. 4, the method for preparing the three-dimensional memory according to this embodiment includes steps S1 to S11.

In step S1, a plurality of stack layers are deposited on a substrate, where each of the plurality of stack layers includes a sacrificial layer and an insulating layer.

For example, the substrate includes a silicon wafer substrate 10, a material of the sacrificial layer 202 may be silicon nitride or silicon nitride doped with other components (such as carbon), and a material of the insulating layer 201 may be silicon oxide or a low dielectric constant (low-k) material.

In step S2, the plurality of stack layers are etched to synchronously form a plurality of channels and word line cuts.

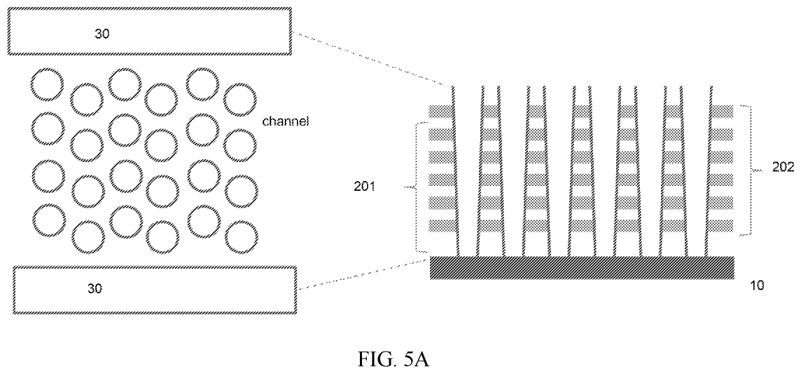

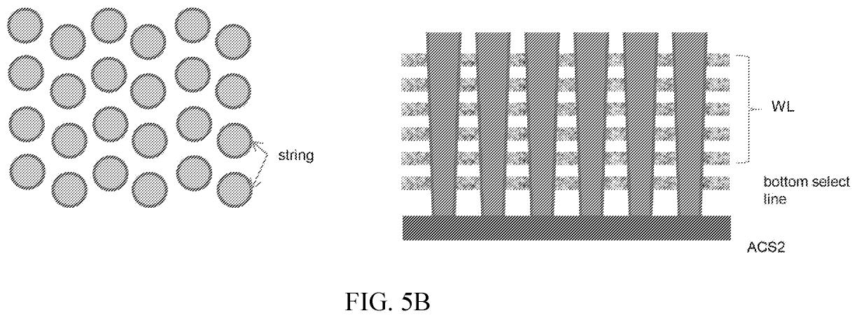

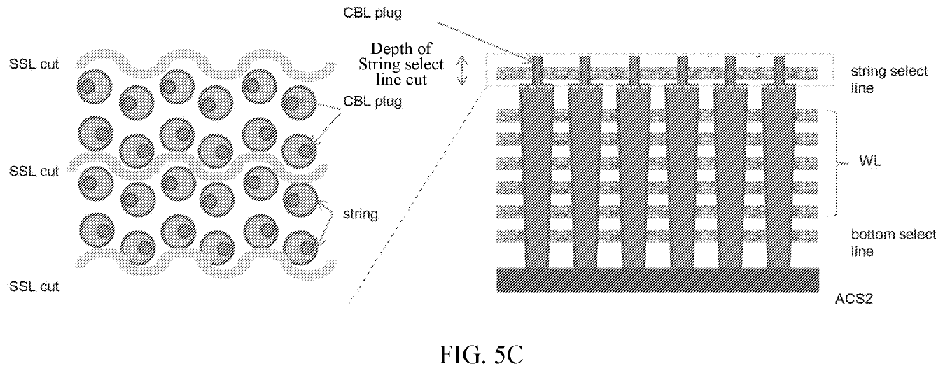

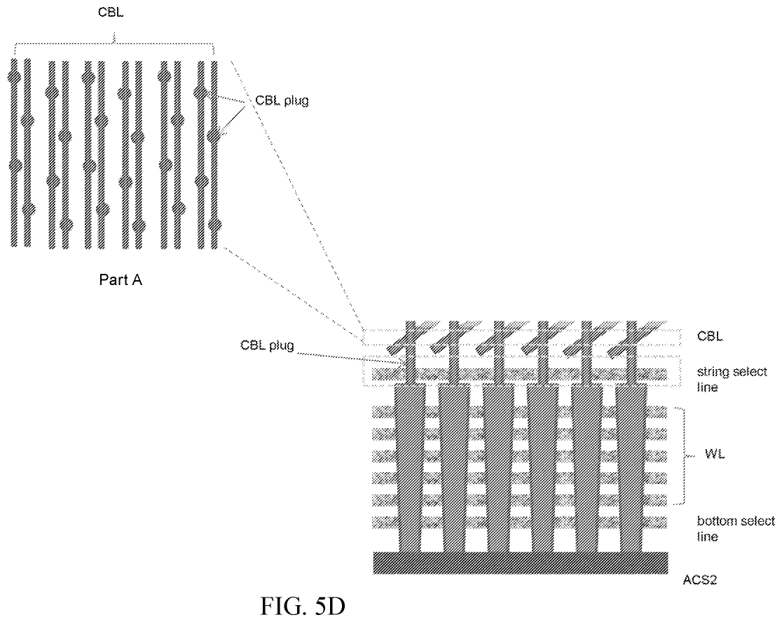

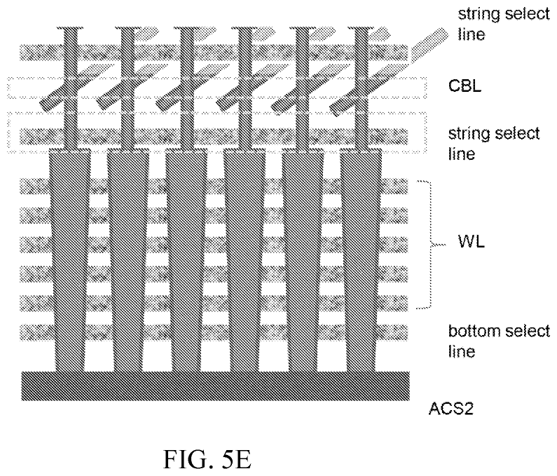

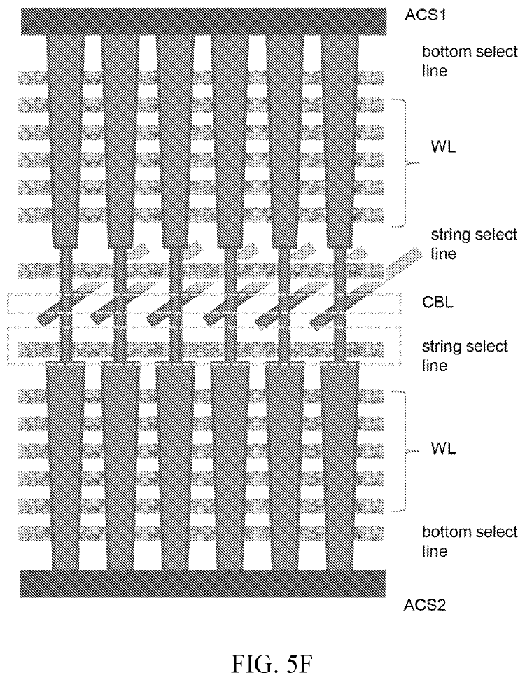

FIG. 5A schematically shows a sectional view and a partial top-view cross-sectional view of channels and word line cuts obtained by synchronously etching according to another embodiment of the present disclosure, where the left figure is the top-view cross-sectional view, and the right figure is the sectional view. Specifically, as shown in FIG. 5A, the channels (channel) and the word line cuts 30 are formed by synchronously etching, a width of the word line cut 30 is greater than twice a diameter of the channel, and the word line cut is provided on opposite sides of the plurality of channels.

In step S3, the plurality of channels and the word line cuts are synchronously filled with a gate stack and a core insulating layer.

The plurality of channels and the word line cuts are first filled with the gate stack of the memory cell synchronously, where the gate stack may be, for example, a TANOS structure. Then the plurality of channels and the word line cuts are filled with a core insulating layer, where a material of the core insulating layer may be, for example, silicon oxide.

Since the width of the word line cut is greater than twice the diameter of the channel, the word line cut remains open when the channel is fully filled.

In step S4, wet etching is performed on the gate stack and the core insulating layer in the word line cut.

Wet etching is performed on the gate stack and the core insulating layer in the word line cut. Since the channel is fully filled, only small amount of etching occurs.

In step S5, the sacrificial layers in the plurality of stack layers are removed and replaced with word line layers, and then a planarization process is performed, so as to form a lower second sub-block.

After the material of a lower sacrificial layer is removed, the lower sacrificial layer is replaced with a word line layer, where the word line layer is made of metal, such as metal tungsten or metal molybdenum.

FIG. 5B schematically shows a sectional view and a partial top-view cross-sectional view of a lower second sub-block according to another embodiment of the present disclosure, where the left figure is the top-view cross-sectional view and the right figure is the sectional view. As shown in FIG. 5B, after step S3 to step S5 and an overall planarization process are performed, a lower structure, i.e., the lower second sub-block may be formed. The second sub-block includes a second common source (ACS2) at the bottom, a bottom select line, word lines (WL), and a plurality of strings that pass through the bottom select line and the word lines and are arranged in a staggered manner.

In step S6, an insulating layer, a string select line cut and an insulating layer are sequentially deposited on the second sub-block.

In this embodiment, the string select line may be made of a metal material such as tungsten, or polysilicon.

In step S7, a plurality of center bit line plugs are formed by etching, and an insulating layer and a core metal layer are sequentially deposited in each of the center bit line plugs.

The insulating layer is deposited on an inner sidewall of each center bit line plug, and then the core metal layer is deposited in the core of each center bit line plug.

In this embodiment, the plurality of center bit line plugs are arranged at intervals, each of the center bit line plugs is eccentrically arranged with respect to a string connected with the center bit line plug, and the core metal layer includes tungsten.

In step S8, the string select line cut is etched and filled with an insulating layer, and a planarization process is performed, so as to form a lower string select line.

In this embodiment, the string select line cut is serpentine-like, and the cut is not deeper than a top of the string of the lower second sub-block. Thus, the cutting depth of the string select line is controlled to ensure that a gap is left between the bottom of the string select line and the top of the string of the second sub-block, where an insulating layer is deposited in the gap.

FIG. 5C schematically shows a sectional view and a partial top-view cross-sectional view of a lower string select line according to another embodiment of the present disclosure, where the left figure is the top-view cross-sectional view and the right figure is the sectional view. As shown in FIG. 5C, after steps S6 to S8 and an overall planarization process are performed, the lower string select line may be formed. It may be seen from the figure that, along the second direction (i.e., the direction in which the plurality of center bit lines are arranged in parallel), each string select line cuts in a staggered manner along a direction in which the plurality of strings are arranged, so as to form a serpentine-like cut. For example, in the top-view cross-sectional view, that is, at the same height in the first direction, three serpentine-like cuts (SSL cut) are provided, so that the plurality of strings are evenly distributed in the second direction.

In step S9, a plurality of center bit lines are formed on the string select line.

FIG. 5D schematically shows a sectional view and a partial top-view cross-sectional view of a center bit line according to another embodiment of the present disclosure, where “part A” on the upper left is the top-view cross-sectional view and the right figure is the sectional view.

As shown in FIG. 5D, in this embodiment, a direction in which the plurality of center bit lines are arranged intersects with a direction in which the word line layers are arranged, the center bit line plugs are arranged at intervals, and the plurality of center bit lines are formed after an overall planarization process is performed. It may be seen from part A that in the top-view cross-sectional view, the center bit line plugs pass through the center bit lines, and the center bit line plugs pass through the center bit lines in a staggered manner, so that all the center bit line plugs are arranged in a staggered manner to achieve connections at every other position.

In step S10, the above steps S6 to S8 are repeated to form an upper string select line.

FIG. 5E schematically shows a partial sectional structural diagram of an upper string select line according to another embodiment of the present disclosure.

As shown in FIG. 5E, the preparation process of the lower string select line in the above steps S6 to S8 is repeated to form the upper string select line.

In step S11, the above steps S3 to S5 are repeated to form an upper first sub-block.

FIG. 5F schematically shows a sectional structural diagram of an upper first sub-block according to another embodiment of the present disclosure.

As shown in FIG. 5F, the preparation process of the lower second sub-block in the above steps S3 to S5 is repeated to form the upper first sub-block.

According to the above embodiments, the method for preparing the three-dimensional memory provided in the present disclosure has high process feasibility and strong practical prospects.

It will be noted that the embodiments of the various steps shown in FIG. 4 and FIG. 5A to FIG. 5F are only examples of how to apply the preparation process of the memory cell provided in the present disclosure on related conventional device structure. In the present disclosure, any preparation process that is capable of forming the various partial structures and mutual positional relationships of the above-mentioned three-dimensional memory falls within the protection scope of the present disclosure.

In addition, the preparation process method used in the embodiments of the present disclosure is not limited to the above-mentioned embodiments, and it may be replaced by other mature process methods in the related art, which does not constitute a limitation on the embodiments of the present disclosure.

It may be seen from the above description that the above embodiments of the present disclosure achieve at least the following technical effects:
(1) According to the present disclosure, the three-dimensional semiconductor memory structure having the center bit lines is combined with the integration technology, so as to arrange the center bit lines inside the memory array to drive the strings in two directions;
(2) According to the present disclosure, based on the number of the layers of the embedded word lines in the array, the block size may be reduced to ½, ⅓ or even 1/n, which may not only reduce the block size, but also reduce the channel length (i.e., the channel resistance), which is in line with the future development trends of three-dimensional memories;
(3) The preparation method provided in the present disclosure has high process feasibility and strong practical prospects.

It will be understood by those skilled in the art that the features recited in the various embodiments and/or claims of the present disclosure may be combined and/or integrated in various ranges, even if such combinations or integrations are not explicitly listed in the present disclosure. In particular, various combinations and/or integrations of features recited in the various embodiments and/or claims of the present disclosure may be made without departing from the spirit and teachings of the present disclosure. All such combinations and/or integrations fall within the scope of the present disclosure.

Although the present disclosure has been illustrated and described with reference to the specific exemplary embodiments of the present disclosure, those skilled in the art will understand that various modifications in form and details may be made to the present disclosure without departing from the spirit and scope of the present disclosure as defined by the appended claims and their equivalents. Therefore, the scope of the present disclosure should not be limited to the above-described embodiments, but should be determined not only by the appended claims but also by the equivalents of the appended claims.

1. A center bit line architecture for three-dimensional memory, comprising:
a first common source and a second common source arranged opposite to each other;
a plurality of word line layers stacked between the first common source and the second common source along a first direction;
a plurality of channels passing through the plurality of word line layers and connected to the first common source and the second common source, wherein a string is formed in each of the plurality of channels; and
a plurality of center bit lines arranged in a middle part of the channels, and arranged at intervals along a second direction intersecting with the first direction,
wherein a combination of the plurality of word line layers and a plurality of strings forms a block, and the plurality of center bit lines divide the block into an upper first sub-block and a lower second sub-block, so as to drive strings in the first sub-block and strings in the second sub-block separately.

2. The center bit line architecture for three-dimensional memory according to claim 1, wherein the plurality of word line layers are spaced apart from each other, and an insulating layer is arranged between two adjacent word line layers.

3. The center bit line architecture for three-dimensional memory according to claim 1, wherein each of a word line layer in the first sub-block closest to the first common source and a word line layer in the second sub-block closest to the second common source is configured as a bottom select line; and
wherein each of a word line layer in the first sub-block closest to the center bit line and a word line layer in the second sub-block closest to the center bit line is configured as a string select line.

4. The center bit line architecture for three-dimensional memory according to claim 3, wherein channels in the first sub-block are connected with channels in the second sub-block respectively through a plurality of center bit line plugs arranged in the middle part, and the center bit line plugs pass through the plurality of center bit lines in a staggered manner.

5. The center bit line architecture for three-dimensional memory according to claim 4, wherein each of the center bit line plugs is eccentrically arranged with respect to a string connected with the center bit line plug.

6. The center bit line architecture for three-dimensional memory according to claim 4, wherein a plurality of string select lines are provided, and each of the plurality of string select lines cuts in a staggered manner along a direction in which the plurality of strings are arranged, so as to form a serpentine-like cut.

7. A three-dimensional memory, comprising:
the center bit line architecture for three-dimensional memory according to claim 1.

8. A method for preparing the three-dimensional memory according to claim 7, comprising:
step S1, depositing a plurality of stack layers on a substrate, wherein each of the plurality of stack layers comprises a sacrificial layer and an insulating layer;
step S2, etching the plurality of stack layers to synchronously form a plurality of channels and word line cuts;
step S3, synchronously filling the plurality of channels and the word line cuts with a gate stack and a core insulating layer;
step S4, performing wet etching on the gate stack and the core insulating layer in the word line cuts;
step S5, removing the sacrificial layers in the plurality of stack layers to replace the sacrificial layers with word line layers, and performing a planarization process, so as to form a lower second sub-block;
step S6, sequentially depositing an insulating layer, a string select line cut and an insulating layer on the second sub-block;
step S7, forming a plurality of center bit line plugs by etching, and sequentially depositing an insulating layer and a core metal layer in each of the center bit line plugs;
step S8, etching the string select line cut, filling the string select line cut with an insulating layer, and performing a planarization process, so as to form a lower string select line;
step S9, forming a plurality of center bit lines on the string select line;
step S10, repeating the steps S6 to S8 to form an upper string select line; and
step S11, repeating the steps S3 to S5 to form an upper first sub-block.

9. The method according to claim 8, wherein in step S1, the substrate comprises a silicon wafer substrate, a material of the sacrificial layer is silicon nitride or doped silicon nitride, and a material of the insulating layer is silicon oxide or a low dielectric constant material.

10. The method according to claim 8, wherein in step S2, a width of the word line cut is greater than twice a diameter of the channel, and the word line cuts are respectively provided on opposite sides of the plurality of channels.

11. The method according to claim 8, wherein in step S3, the gate stack comprises a TANOS structure, and a material of the core insulating layer comprises silicon oxide.

12. The method according to claim 8, wherein in step S5, a material of the word line layer comprises metal tungsten or metal molybdenum.

13. The method according to claim 8, wherein in step S6, a material of the string select line is a metal material comprising tungsten, or polysilicon.

14. The method according to claim 8, wherein in step S7, the plurality of center bit line plugs are arranged at intervals, each of the center bit line plugs is eccentrically arranged with respect to a string connected with the center bit line plug, and the core metal layer comprises tungsten.

15. The method according to claim 8, wherein in step S8, the string select line cut is serpentine-like, and the string select line cut is not deeper than a top of string of the second sub-block.

16. The method according to claim 8, wherein in step S9, a direction in which the plurality of center bit lines are arranged intersects with a direction in which the word line layers are arranged, the center bit line plugs are arranged at intervals, and the plurality of center bit lines are formed after a planarization process is performed.
